(19) United States
(12) Patent Application Publication
(10) Pub. No.: US 2023/0166142 A1
(43) Pub. Date: Jun. 1, 2023

(54) FIRE-EXTINGUISHING DEVICE FOR A VEHICLE BATTERY

(71) Applicants: HYUNDAI MOTOR COMPANY, Seoul (KR); KIA CORPORATION, Seoul (KR)

(72) Inventor: Hyeon Gi Shin, Yongin-si (KR)

(73) Assignees: HYUNDAI MOTOR COMPANY, Seoul (KR); KIA CORPORATION, Seoul (KR)

(21) Appl. No.: 17/975,149

(22) Filed: Oct. 27, 2022

(30) Foreign Application Priority Data
Nov. 30, 2021 (KR) 10-2021-0168136

(51) Int. Cl. A62C 5/00; A62C 3/16; A62C 3/07; A62C 37/40; H01M 50/383; H01M 50/333

(52) U.S. Cl. CPC A62C 5/004; A62C 3/07; A62C 3/16; A62C 37/40; H01M 50/333; H01M 50/383; H01M 2220/20

(57) ABSTRACT

A fire-extinguishing device for a vehicle battery includes: a gas discharge part installed in a battery pack and configured to discharge gas inside the battery pack; a gas path part configured to permit the flow of gas generated in the battery pack and discharged through the gas discharge part in the event of a fire; a catalytic converter installed in the gas path part and configured to convert carbon monoxide in gas flowing through the gas path part into carbon dioxide; and a fire-extinguishing agent tank configured to store a fire-extinguishing agent and to be connected to the gas path part. The fire-extinguishing agent tank allows the carbon dioxide converted by the catalytic converter to flow thereinto. The fire-extinguishing device for a vehicle battery further includes a fire-extinguishing agent supply path part connecting the fire-extinguishing agent tank to the battery pack.

### CROSS-REFERENCE TO RELATED APPLICATION

This application claims under 35 U.S.C. §119(a) the benefit of priority to Korean Patent Application No. 10-2021-0168136 filed on Nov. 30, 2021, the entire contents of which are incorporated herein by reference.

### BACKGROUND

### (a) Technical Field

The present disclosure relates to a fire-extinguishing device for a vehicle battery. More particularly, it relates to a fire-extinguishing device for a vehicle battery capable of quickly and accurately detecting a fire occurring in a battery pack, and effectively extinguishing the fire immediately upon detection.

### (b) Background Art

Recently, due to concerns regarding issues such as energy efficiency, environmental pollution, and fossil fuel depletion, an eco-friendly vehicle that may substantially replace an internal combustion engine vehicle has been developed.

Examples of the eco-friendly vehicle include: a battery electric vehicle (BEV) using a battery as a power source; a fuel-cell electric vehicle (FCEV) using a fuel cell as a main power source; and a hybrid electric vehicle (HEV) using both an engine and a motor as driving sources to drive the vehicle.

What all of these eco-friendly vehicles (xEVs) have in common is that a motor is driven using power recharged in the battery to drive, which is essentially the way that electric vehicles are propelled. Such electric vehicles include a high-voltage battery pack mounted therein that supplies power to the motor. The high-voltage battery pack supplies power to an electrical component in the vehicle, such as a motor, while repeatedly performing recharging and discharging during the operation of the vehicle.

The battery pack in the electric vehicle is normally formed of a battery case, a battery module located inside the battery case, and a battery management system (BMS). The BMS is configured to collect pieces of information such as the voltage, current, and temperature of cells forming the battery module and to control the operation of the cells. Additionally, the battery pack is configured to prevent the occurrence of a fire by breaking a fuse or turning off a relay connected to an inverter when an internal short circuit occurs, or overcurrent flows occur.

In an electric vehicle, a fire may occur inside the battery pack while the vehicle is driving due to various reasons such as a collision and malfunction of parts. If the fire in the battery pack is not extinguished, the vehicle may be completely burned, leading to significant loss and injury. Recently, the use of electric vehicles has increased, and it has become necessary to be careful with regard to the risk of a fire caused by an external impact, an internal short circuit in the battery, or peripheral high-voltage electrical wiring.

Particularly, a battery fire may spread in a short time due to the internal and external structures and components of the battery. Further, since a public transportation vehicle such as a bus has many passengers on board, it is required to rapidly extinguish a fire for passenger safety. If the fire is not extinguished in an initial stage, a major disaster may occur.

Currently, as a method of responding to a fire occurring in a vehicle, a fire extinguisher is installed in the vehicle and used for the fire. In this case, if a driver fails to use the fire extinguisher in time, the fire may not be extinguished at the initial stage and the vehicle may be completely burned, which also results in a major disaster. Furthermore, when a fire occurs in a battery, it is very difficult to completely extinguish the fire using a small fire extinguisher or by spraying a fire-extinguishing agent due to the internal materials of the battery.

Further, since the driver is inside the vehicle while the vehicle is traveling, it is difficult to detect the fire occurring in the battery before the driver notices a large amount of smoke. Additionally, unlike a passenger car, a bus has a large and long body, so it is more difficult to notice that a fire has occurred.

Furthermore, in the case of large vehicles, such as large busses, there is an external protective structure, such as a battery case, that covers the battery cells in a battery pack mounted on a vehicle roof. Accordingly, even if a driver notices the fire in time, it is difficult for the driver to spray a fire-extinguishing agent into the battery case. Even if the driver does spray the fire-extinguishing agent thereinto, the fire-extinguishing agent may not reach the battery cell in the battery case as desired. Therefore, it is difficult to extinguish the fire effectively.

Particularly, in the related art, a plurality of battery packs are mounted in a large bus or the like, and in order to detect the corresponding battery pack in which a fire occurs, each of the battery packs has an expensive fire detector installed therein, which causes a significant increase in costs. In addition, even if an expensive gas detector (e.g., gas concentration measurement sensor) that detects gas concentration is installed for each of the battery packs as a fire detector, there is the possibility that erroneous detection of gas concentration may occur.

The above information disclosed in this Background section is only to enhance understanding of the background of the disclosure. Therefore, the Background section may contain information that does not form the prior art that is already known in this country to a person of ordinary skill in the art.

### SUMMARY

The present disclosure has been made in an effort to solve the above-described problems associated with the prior art. It is an object of the present disclosure to provide a fire-extinguishing device for a vehicle battery capable of quickly and accurately detecting a fire occurring in a battery pack, and effectively extinguishing the fire immediately upon detection.

The objects of the present disclosure are not limited to the above-mentioned objects. Further, other objects not yet mentioned should be clearly understood by those having ordinary skill in the art to which the present disclosure pertains from the following descriptions.

In one aspect, the present disclosure provides a fire-extinguishing device for a vehicle battery including: a gas discharge part installed in a battery pack and configured to discharge gas inside the battery pack; a gas path part configured to permit flow of gas generated in the battery pack and discharged through the gas discharge part in an event of a fire; a catalytic converter installed in the gas path part and configured to convert carbon monoxide in gas flowing through the gas path part into carbon dioxide; and a fire-extinguishing agent tank configured to store a fire-extinguishing agent and to be connected to the gas path part. The fire-extinguishing agent tank allows carbon dioxide converted by the catalytic converter to flow thereinto. The fire-extinguishing device for a vehicle battery further includes a fire-extinguishing agent supply path part connecting the fire-extinguishing agent tank to the battery pack. To extinguish the fire, the gas flowing into the fire-extinguishing agent tank and the fire-extinguishing agent stored therein may be supplied from the fire-extinguishing agent tank to the battery pack through the fire-extinguishing agent supply path part by the pressure in the fire-extinguishing agent tank. The pressure in the fire-extinguishing agent tank rises while the gas passing through the catalytic converter flows into the fire-extinguishing agent tank.

Other aspects and embodiments of the disclosure are discussed below.

It is understood that the term “vehicle,” or “vehicular,” or other similar terms as used herein is inclusive of motor vehicles in general. Such motor vehicles may encompass passenger automobiles including sports utility vehicles (SUV), buses, trucks, various commercial vehicles, watercraft including a variety of boats and ships, aircraft, and the like. Such motor vehicles may also include hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles.

The above and other features of the disclosure are discussed below.

### BRIEF DESCRIPTION OF THE DRAWINGS

The above and other features of the present disclosure are described in detail with reference to certain embodiments thereof illustrated in the accompanying drawings, which are given hereinbelow by way of illustration only, and thus are not limitative of the present disclosure, and wherein:

FIG. 1 is a view showing the state in which a well-known pressure-balancing element is installed in a battery case;

FIG. 2 is a perspective view showing the well-known pressure-balancing element;

FIG. 3 is an overall block diagram showing a fire-extinguishing device according to an embodiment of the present disclosure;

FIG. 4 is a block diagram showing a detection element, a control element, and an operating element in the fire-extinguishing device according to an embodiment of the present disclosure;

FIG. 5 is a cross-sectional view showing a pressure-balancing element installed in a battery case of a battery pack in an embodiment of the present disclosure;

FIGS. 6 and 7 are cross-sectional views showing the configuration of a ventilation valve in the fire-extinguishing device according to an embodiment of the present disclosure;

FIGS. 8 and 9 are views showing an operation state of an auxiliary fire detector provided in the ventilation valve in an embodiment of the present disclosure;

FIG. 10 is a view showing the configuration of a catalytic converter usable in the fire-extinguishing device according to an embodiment of the present disclosure;

FIG. 11 is a flowchart showing the overall operation process of a battery fire-extinguishing device according to an embodiment of the present disclosure;

FIG. 12 is a flowchart showing the operation process of the battery fire-extinguishing device according to an embodiment of the present disclosure when a battery fire occurs; and

FIGS. 13 and 14 are views showing a gas flow path in the battery fire-extinguishing device according to an embodiment of the present disclosure when a battery fire occurs.

It should be understood that the appended drawings are not necessarily to scale, presenting a somewhat simplified representation of various features illustrative of the basic principles of the disclosure. The specific design features of the present disclosure as disclosed herein, including, for example, specific dimensions, orientations, locations, and shapes, are determined in part by the particular intended application and use environment.

In the figures, reference numbers refer to the same or equivalent parts of the present disclosure throughout the several figures of the drawings.

### DETAILED DESCRIPTION

Specific structural or functional descriptions made in connection with the embodiments of the present disclosure are merely illustrative for the purpose of describing embodiments according to the concept of the present disclosure. The embodiments, according to the concept of the present disclosure, may be implemented in various forms. Further, it should be understood that the present description is not intended to limit the disclosure to those embodiments. On the contrary, the disclosure is intended to cover not only the embodiments described, but also various alternatives, modifications, equivalents, and other embodiments which may be included within the spirit and scope of the inventive concept as defined by the appended claims.

In the present disclosure, terms such as “first” and/or “second” may be used to describe various components, but the components are not limited by the terms. The terms are used only for the purpose of distinguishing one component from other components. For example, a first component may be referred to as a second component, and similarly, a second component may also be referred to as a first component without departing from the scope of rights according to the concept of the present disclosure.

When one component is referred to as being “connected” or “joined” to another component, the one component may be directly connected or joined to the other component, but it should be understood that other components may be present therebetween. On the other hand, when the one component is referred to as being “directly connected to” or “directly in contact with” the other component, it should be understood that other components are not present therebetween. Other expressions for the description of relationships between components, i.e., “between” and “directly between” or “adjacent to” and “directly adjacent to,” should be interpreted in the same manner.

The same reference numerals represent the same components throughout the specification. Additionally, the terms in the specification are used merely to describe embodiments and are not intended to limit the present disclosure. In this specification, an expression in a singular form also includes a plural form unless otherwise clearly specified in context. As used herein, expressions such as “comprise” and/or “comprising” do not exclude the presence or addition of one or more components, steps, operations, and/or elements other than those described.

When a component, device, element, or the like of the present disclosure is described as having a purpose or performing an operation, function, or the like, the component, device, or element should be considered herein as being “configured to” meet that purpose or to perform that operation or function.

Hereinafter, the present disclosure is described in detail with reference to the accompanying drawings.

An object of the present disclosure is to provide a fire-extinguishing device for a vehicle battery capable of quickly and accurately detecting a fire occurring in a battery pack and effectively extinguishing the fire immediately upon detection.

If it is possible to detect a fire occurring in the battery pack of a vehicle at an early stage, a prompt warning may be given to allow a driver and a passenger to escape from the vehicle quickly and safely in the event of a fire.

To this end, the fire-extinguishing device, according to the present disclosure, is configured to detect the fire occurring in the battery pack at the early stage, and to issue a warning and perform an automatic fire-extinguishing operation immediately upon detection.

The general cause of a fire in a battery mounted in an electric vehicle is described as follows. When an overvoltage occurs in the battery or an external impact is applied thereto, a separator may break. Further, when the separator is damaged, thermal decomposition of electrolytes may occur.

In this case, hot-temperature flammable (e.g., combustible) gas is discharged from a battery cell. When a battery fire test is performed, it can be seen that the main component of the flammable gas is carbon monoxide (CO). Further, the time at which the flammable gas is discharged is the initial stage at which the fire can be extinguished.

When gas expands in the battery and the gas and electrolytes leak out of the battery cell, thermal runaway may occur, which leads to the battery exploding. It is almost impossible to extinguish the fire from that point in time. Therefore, it is required to quickly detect the discharge of flammable gas and spray a fire-extinguishing agent on the battery pack where the fire occurs at the point of discharge of the flammable gas, thereby making it possible to extinguish the fire at the initial stage.

In the present disclosure, a fire is detected by detecting gas discharged from the battery cell in or at the initial stage in which it is possible to extinguish the fire in the battery cell, i.e., in the stage of discharging flammable gas. In other words, the occurrence of a fire is determined in the early stage by detecting the gas discharged from the battery cell due to the thermal decomposition of electrolytes therein.

In this case, a pressure-balancing element installed in the battery pack is used to detect gas. The pressure-balancing element is essentially required to be mounted in the battery pack mounted in the vehicle.

A vehicle battery pack of the related art includes a battery case and a battery module disposed inside the battery case. The battery module is formed of a plurality of unit cells, i.e., battery cells. Additionally, the battery cells forming the battery module in the battery pack remain sealed inside the battery case.

In this configuration, the internal temperature of the battery case repeatedly rises and falls with the recharging and discharging operations of the battery cells. When the internal temperature repeatedly rises and falls, it is required to provide a path through which the gas may move between the inside of the battery case and the outside thereof.

The internal pressure and the external pressure of the battery case may be maintained uniformly only when a gas inlet/outlet is provided in the battery case, thereby making it possible to prevent the battery pack from expanding or contracting. To this end, the battery case in the battery pack includes a pressure-balancing element configured to provide a path through which gas may move between the inside of the battery case and the outside thereof.

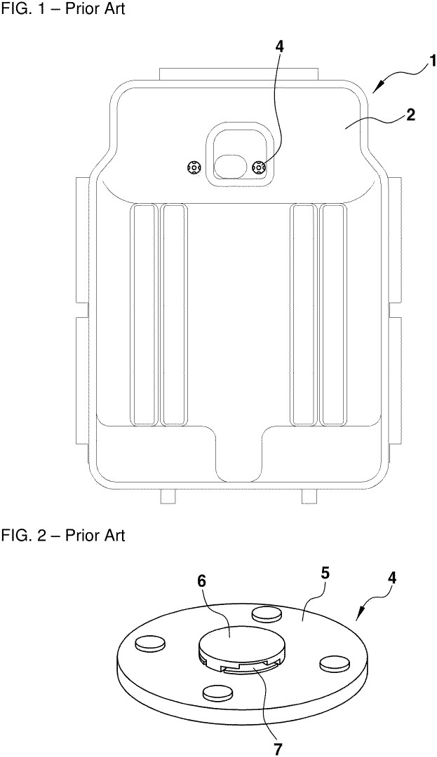

FIG. 1 is a view showing the state in which a well-known pressure-balancing element is installed in the battery case. As shown in FIG. 1, a pressure-balancing element 4, through which gas moves between the inside of a battery case 2 and the outside thereof, is installed in the battery case 2 of a battery pack 1. The pressure-balancing element 4 has a path through which the gas moves between the inside of the battery case 2 and the outside thereof.

A battery module (not shown) is stored in the battery case 2 shown in FIG. 1, and battery cells of the battery module remain sealed by the battery case 2. In the battery pack 1, the internal temperature of the battery case 2 repeatedly rises and falls with the recharging and discharging operations of the battery cell.

In order to prevent the battery case 2 from expanding or contracting, a plurality of pressure-balancing elements 4 are installed in the battery case, as shown in the drawing. Thus, the plurality of pressure-balancing elements 4 allow gas to move between the inside of the battery case 2 and the outside thereof through the gas path formed in the pressure-balancing element at normal times (i.e., when no fire occurs). Accordingly, expansion and contraction of the battery case 2 may be prevented, and the pressure between the inside of the battery case 2 and the outside thereof may be maintained uniformly.

FIG. 2 is a perspective view showing a well-known pressure-balancing element as a reference view for easy understanding of the present disclosure. As shown in FIG. 2, a well-known pressure-balancing element 4 is formed of a plate 5 fixed to and in close contact with the outer surface of the battery case (reference numeral “2” in FIG. 1), and a vent part 6 integrally provided in the center of the plate 5.

The vent part 6, disposed in the center of the well-known pressure-balancing element 4, has a plurality of vent holes 7 formed therein as a path through which gas may move between the inside of the battery case 2 and the outside thereof.

Accordingly, gas passes through each vent hole 7 in the vent part 6 where the plate 5 is fixed to the outer surface of the battery case 2, thereby performing pressure balancing between the inside of the battery case and the outside thereof.

In the well-known pressure-balancing element 4, the vent hole 7 is formed to be small in order to prevent external moisture from flowing into the battery case 2 through the vent hole (gas path) 7 formed in the vent part 6.

Accordingly, since one vent hole 7 may not perform sufficient pressure control (pressure balancing), a plurality of small-sized vent holes 7 are provided in each of the pressure-balancing elements 4, and a plurality of pressure-balancing elements 4 are installed in each of the battery packs 1.

The present disclosure provides a pressure-balancing element and a ventilation valve having a new configuration capable of performing a pressure control (pressure balancing) function inside the battery pack at normal times. The pressure-balancing element and the ventilation valve further have a new configuration capable of performing a function of discharging gas generated from the battery cell only to a path at which a gas detector is disposed (a gas path part to be described below) without discharging the gas to the outside in the event of a fire.

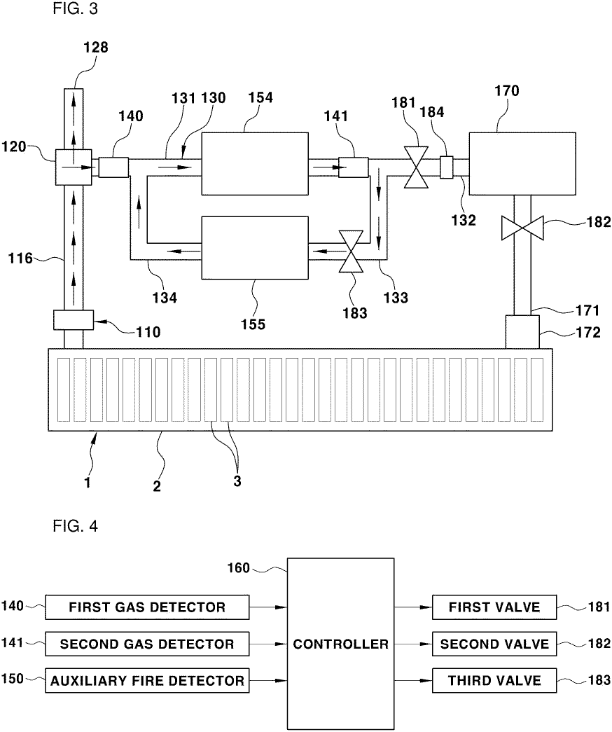

FIG. 3 is an overall block diagram of a fire-extinguishing device according to an embodiment of the present disclosure. FIG. 3 shows the fire-extinguishing device configured to detect fire occurring in the battery pack 1 in the early stage and to automatically extinguish the fire immediately upon detection. FIG. 4 is a block diagram showing a detection element, a control element, and an operating element in the fire-extinguishing device according to an embodiment of the present disclosure.

The configuration of the fire-extinguishing device is described in detail below. The fire-extinguishing device, according to an embodiment of the present disclosure, is installed in the battery pack 1 and includes a gas discharge part configured to discharge gas inside the battery case 2.

In an embodiment of the present disclosure, the gas discharge part may be a pressure-balancing element 110 installed in the battery case 2 to provide a path through which gas moves between the inside of the battery case 2 and the outside thereof.

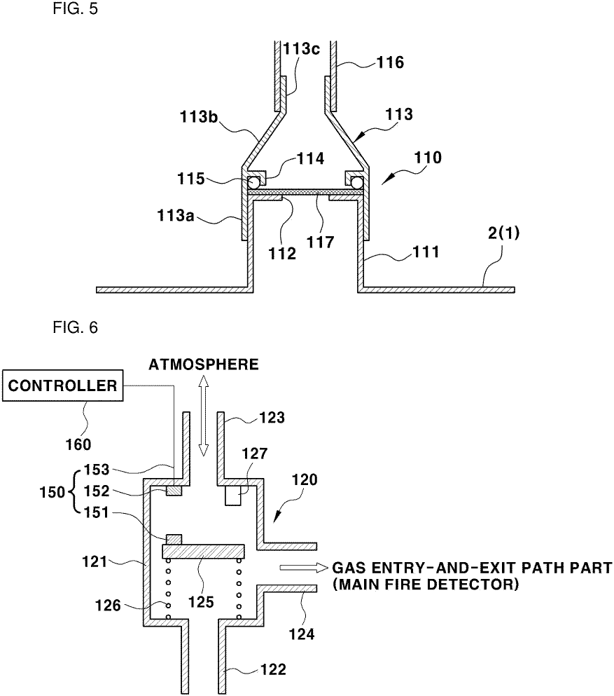

FIG. 5 is a cross-sectional view showing the pressure-balancing element installed in the battery case of the battery pack in an embodiment of this disclosure. As shown in FIG. 5, the pressure-balancing element 110 includes a vent part 111 provided in the battery case 2 of the battery pack 1. The vent part 111 includes: a vent hole 112 through which gas may pass between the inside of the battery case 2 and the outside thereof; a connector 113 coupled to the vent part 111 so that an internal space thereof communicates with the vent hole 112 in the vent part 111; and a venting path part 116 formed to extend from the connector 113 by a predetermined length. The venting path part 116 has an internal space communicating with an internal space in the connector 113, the vent hole 112, and an internal space in the vent part 111.

As described herein, in the well-known pressure-balancing element 4, the vent hole 7 in the vent part 6, formed as a gas path, is formed so as to have a very small size and a very small flow path cross-sectional area in order to prevent moisture inflow. In the pressure-balancing element 110 of the present disclosure, the vent hole 112 has a relatively large size. Further, a relatively large flow path cross-sectional area is formed in the vent part 111, the connector 113, and the venting path part 116, extending from the vent hole 112 by a predetermined length. Therefore, when airtightness is maintained only in a connection portion between these components, there is little possibility of moisture flowing into the battery case 2 through the venting path part 116 having the predetermined length.

In an embodiment, the vent hole 112 in the vent part 111 may have a ventilation waterproofing membrane member 117 installed thereover that allows gas to pass therethrough and prevents moisture outside from flowing thereinto. In this case, the ventilation waterproofing membrane member 117 is installed so as to have a structure that blocks the vent hole 112 in the vent part 111, as shown in FIG. 5.

In an embodiment of the present disclosure, as the ventilation waterproof membrane member 117, a fluorine resin membrane that blocks moisture and allows gas to pass therethrough may be used. Specifically, a film made of expanded polytetrafluoroethylene (ePTFE), known by the trade name Gore-Tex®, and a film-shaped member may be used.

It is desirable to use the ventilation waterproofing membrane member 117 because it is capable of discharging moisture inside the battery case 2 and preventing moisture outside the battery case 2 from flowing into the battery case 2 through the vent hole 112 in the vent part 111.

The vent part 111 may be formed to have a tubular shape protruding outwards from the surface of the battery case 2, and the vent hole 112, having a predetermined diameter or size, is formed at a protruding end of the vent part 111. In an embodiment of the present disclosure, the vent part 111 may be formed as a tube having a circular cross-section, i.e., a circular tube shape protruding outwards from the surface of the battery case 2.

The connector 113 has a large-diameter part 113a having a relatively large diameter formed at one end thereof and a small-diameter part 113c having a smaller diameter than the large-diameter part 113a formed at the other end thereof. The large-diameter part 113a and the small-diameter part 113c are connected by a reduced tube part 113b, the diameter of which is gradually reduced.

The large-diameter part 113a may be screwed or otherwise connected to the outer circumferential surface of the vent part 111. To this end, a thread may be formed on the internal circumferential surface of the large-diameter part 113a and on the outer circumferential surface of the vent part 111. In addition, the small-diameter part 113c is coupled to the venting path part 116. For example, the internal circumferential surface of the small-diameter part 113c may be coupled to the outer circumferential surface of the venting path part 116, or the outer circumferential surface of the small-diameter part 113c may be coupled to the internal circumferential surface of the venting path part 116.

In this case, the surfaces of the small-diameter part 113c and the venting path part 116 may be coupled and fixed by thermal fusion. A tubular member such as a hose or a tube may be used as the venting path part 116, and the venting path part 116 may be made of a material capable of being thermally fused to the connector 113.

In addition, a sealing protrusion 114 may be formed to protrude inwards in the radial direction on the internal circumferential surface of the connector 113. The connector 113 and the vent part 111 are screwed together so that the ventilation waterproof membrane member 117 is pressed against the vent part 111 in the state where a sealing member 115 is inserted into the sealing protrusion 114. The sealing member 115 is installed to maintain airtightness (sealing) between the connector 113, the vent part 111, and the ventilation waterproof membrane member 117. The sealing member 115 may be an O-ring made of a material having elasticity, such as rubber. The sealing member 115 may be circular in shape.

The ventilation waterproof membrane member 117 is installed so as to be placed on the outer surface of the protruding end of the vent part 111. When the large-diameter part 113a of the connector 113 is screwed onto the outer circumferential surface of the vent part 111, the ventilation waterproof membrane member 117 is pressed against the vent part 111 by the sealing protrusion 114 and the sealing member 115. The edge portions of the ventilation waterproof membrane member 117 are pressed by the sealing protrusion 114 and the sealing member 115 to be fixed to the outer surface of the protruding end of the vent part 111.

In an embodiment of the present disclosure, the sealing protrusion 114 may be formed to have the shape of a “¬” cross-section (i.e., L-shaped cross-section), one side of which is opened on the internal circumferential surface of the large-diameter part 113a of the connector 113. Accordingly, where the circular sealing member 115 is inserted into the sealing protrusion 114 having the shape of the “¬” cross-section, when the large-diameter part 113a of the connector 113 is screwed to the vent part 111, the sealing member 115 may press the ventilation waterproof membrane member 117 through the open portion of the sealing protrusion 114.

In the present disclosure, it is possible to design the size of the vent hole 112, which is a gas path through which gas passes, without restriction. Particularly, it is possible to form the vent hole 112 larger than the vent hole 112 in the well-known pressure-balancing element 110, thereby having an effect of reducing the number of pressure-balancing elements per battery pack to one.

As shown in FIG. 3, the fire-extinguishing device, according to an embodiment of the present disclosure, may further include a ventilation valve 120 installed on the outlet side of a venting path part (refer to reference numeral “116” in FIG. 5) of the pressure-balancing element 110 installed in the battery pack 1. A gas path part 130 is installed to extend from the ventilation valve 120.

In addition, the fire-extinguishing device, according to an embodiment of the present disclosure, may further include: gas detectors 140 and 141 installed in the gas path part 130; a catalytic converter 154 installed in the gas path part 130 and configured to convert flammable gas discharged from the battery pack 1 through the gas path part 130 and to discharge the same; and a fire-extinguishing agent tank 170. The fire-extinguishing agent tank 170 is configured to store a fire-extinguishing agent that extinguishes a fire in the battery pack 1. The fire-extinguishing device may further include a controller 160 configured to output a control signal to supply the fire-extinguishing agent to the battery pack 1 in which a fire occurs when a first gas detector 140 detects a fire. The fire-extinguishing device may further include valves 181, 182, and 183 that are configured to control opening and closing operations to cause the fire-extinguishing agent stored in the fire-extinguishing agent tank 170 to be supplied to the battery pack 1 in response to the control signal output by the controller 160.

The controller 160 may be a battery management system (BMS). In addition, as one of the gas detectors, the first gas detector 140, configured to detect gas generated and discharged from the battery pack 1, is installed in the gas path part 130 (i.e., a first path part to be described below) between the ventilation valve 120 and the catalytic converter 154.

In addition, as the other one of the gas detectors, the second gas detector 141, configured to detect the gas generated and discharged from the battery pack 1, is installed in the gas path part 130 (i.e., a second path part to be described below) between the catalytic converter 154 and the fire-extinguishing agent tank 170.

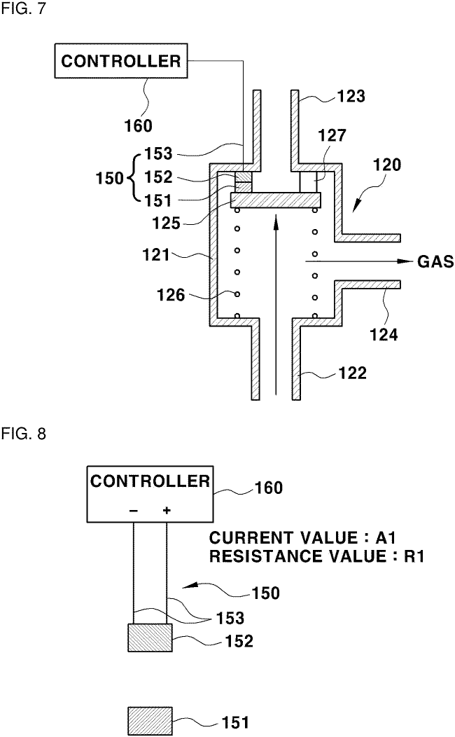

FIGS. 6 and 7 are cross-sectional views showing the configuration of the ventilation valve 120 in the fire-extinguishing device according to an embodiment of the present disclosure. FIG. 6 shows a normal state, and FIG. 7 shows a state when a fire occurs.

As shown in the drawing, the ventilation valve 120 may be formed of a valve housing 121 including: a ventilation port 122 connected to the venting path part 116 of the pressure-balancing element 110; an atmospheric port 123 connected to the atmosphere side; and a connection port 124 to which the gas path part 130 is connected. The ventilation valve 120 may further include a valve body 125 installed in an internal space in the valve housing 121 and configured to be moved to close the atmospheric port 123 by the gas discharged from the battery pack 1 in the event of a fire. Furthermore, the ventilation valve 120 may include a spring 126 installed to support the valve body 125 in the internal space in the valve housing 121.

The valve housing 121 is connected to the venting path part 116 so that the internal space in the valve housing 121 communicates with an internal space in the venting path part 116. Accordingly, the internal space in the valve housing 121 communicates with the internal space in the venting path part 116 and the internal space in the connector 113 of the pressure-balancing element 110. The internal space in the valve housing 121 also communicates with the internal space in the vent part 111 and the internal space in the battery case 2 with the ventilation waterproof membrane member 117 interposed therebetween.

The atmospheric port 123 in the ventilation valve 120 may be formed to be located at an upper end of the valve housing 121, and an entry-and-exit path part (reference numeral “128” in FIG. 3), through which air moves between the same and the atmosphere, may be connected to the atmospheric port 123.

In the ventilation valve 120, the connection port 124 may be formed to be located on the side surface of the valve housing 121. In the ventilation valve 120, the valve body 125 is normally positioned so as to open the atmospheric port 123, and is positioned to be in the open state with respect to the connection port 124 at all times.

The spring 126 is installed to be located below the valve body 125, and maintains the position of the valve body 125 so that the valve body 125 is in a position where the atmospheric port 123 and the connection port 124 are open. Particularly, the spring 126 maintains the position of the valve body 125 so that the connection port 124 is always in an open position not only when a fire occurs but also at normal times.

As shown in FIGS. 6 and 7, the valve body 125 is provided in the shape of the plate 5 and is installed in the internal space in the valve housing 121 in the transverse direction. The spring 126, which is disposed below the valve body 125, is disposed between the valve housing 121 and the valve body 125 so as to support the valve body 125 to be above the spring 126.

As described herein, the connection port 124 is a port that is always open regardless of whether a fire occurs, regardless of whether gas is discharged from the battery pack 1, and regardless of the position of the valve body 125. Referring to FIG. 6, it can be seen that the normal position of the valve body 125, supported by the spring 126, is higher than the position of the connection port 124. Accordingly, the connection port 124 is not a port that is closed by the valve body 125 but a port that is always open.

On the other hand, the atmospheric port 123 is a port that is opened and closed by the valve body 125. In detail, the valve body 125 opens the atmospheric port 123 at normal times, and the atmospheric port 123 is closed by the valve body 125 when a fire occurs.

In the event of a fire, gas generated from the battery pack 1 passes through the pressure-balancing element 110 and flows into the valve housing 121 of the ventilation valve 120 through the ventilation port 122. The gas flowing thereinto pushes the valve body 125 upwards, and the valve body 125 overcomes the force of the spring 126 and moves toward the atmospheric port 123 to close the atmospheric port 123. The connection port 124 maintains the open state regardless of the position of the valve body 125, even when a fire occurs.

Accordingly, when the atmospheric port 123 is in the open state, the internal space in the atmospheric port 123 and the valve housing 121, the internal space in the venting path part 116 of the pressure-balancing element 110, the internal space in the connector 113, and the internal space in the vent part 111 with the ventilation waterproof membrane member 117 interposed therebetween, are used as a gas path for pressure balancing between the inside of the battery case 2 and the outside thereof.

Normally, as shown in FIG. 6, gas moves between the inside of the battery pack 1 and the outside thereof through the pressure-balancing element 110 and the ventilation valve 120 when the atmospheric port 123 is open, thereby performing pressure balancing between the inside of the battery pack 1 and the outside thereof.

In the event of a fire, as shown in FIG. 7, the atmospheric port 123 is closed by the valve body 125, so that gas generated from the battery pack 1 is not discharged to the atmosphere. The gas generated from the battery pack 1 may be discharged only through the connection port 124, which is always open, and the gas discharged through the connection port 124 in this manner flows to the first gas detector 140 through the gas path part 130.

Accordingly, gas is detected by the first gas detector 140, and the controller 160 may determine that a fire occurs from the signal received from the first gas detector 140. The gas is a gas generated in the battery pack 1 at the initial stage of a fire. More specifically, a flammable gas generated in the battery cell 3 stored in the battery case 2. A main component of the flammable gas is carbon monoxide (CO).

In an embodiment of the present disclosure, an auxiliary fire detector 150 may be provided in the ventilation valve 120. The auxiliary fire detector 150 is configured to detect the occurrence of a fire inside the battery pack 1 separately from the first gas detector 140.

As shown in FIGS. 6 and 7, the auxiliary fire detector 150 may be formed of a first magnetic resistor 151 installed in the valve body 125 and a second magnetic resistor 152 fixedly installed at a position near the atmospheric port 123 among the internal surfaces of the valve housing 121. The second magnetic resistor 152 is fixedly installed at a position near the atmospheric port 123 so that the first magnetic resistor 151 may be attached thereto when the valve body 125 is moved to a position at which the atmospheric port 123 is closed. The auxiliary fire detector 150 may also formed of a wire 153 configured to connect the first magnetic resistor 151 and the controller 160 to allow conduction therebetween.

Although not shown in the drawing, the controller 160 may include a current application unit configured to apply current to the wire 153 connecting the first magnetic resistor 151 to the controller 160. The controller 160 may also include a current detection unit that is configured to detect the value of current applied to the wire 153. Accordingly, in the controller 160, the current application unit may apply a current of a predetermined value to the wire 153, and the current detection unit may detect a value of the current flowing through the wire 153.

Referring to FIGS. 6 and 7, it can be seen that the first magnetic resistor 151 is attached to one side of the valve body 125, and the second magnetic resistor 152 is attached to a position on one side of the internal surface of the valve housing 121, the position being on one side thereof facing the first magnetic resistor 151. In this structure, a buffer member 127 may be installed on the other side of the valve body 125 or on the other side of the internal surface of the valve housing 121.

The buffer member 127 may be made of a material having elasticity and shock absorption performance, such as rubber. As shown in FIG. 7, the buffer member 127 prevents direct contact between the valve body 125 and the valve housing 121 when the valve body 125 is raised upwards, as seen in the drawing, by the force of gas to close the atmospheric port 123 when a fire occurs. The buffer member 127 also serves to absorb an impact between the valve body 125 and the valve housing 121.

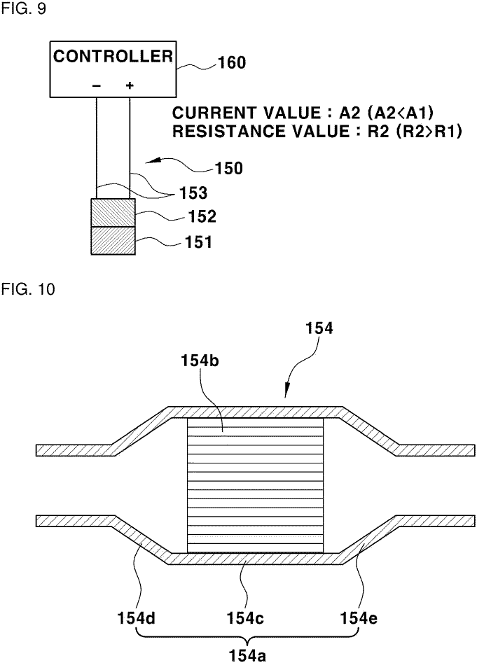

FIGS. 8 and 9 are views showing the operation state of the auxiliary fire detector provided in the ventilation valve 120 in an embodiment of the present disclosure. FIG. 8 shows the state at normal times (when no fire occurs), and FIG. 9 shows the state when a fire occurs.

Normally, as shown in FIG. 8, when current is applied through the wire 153 from the controller 160, only the wire 153 and the second magnetic resistor 152 of the valve housing 121 are in the conductive state. On the other hand, in the event of a fire, when the valve body 125 is raised by the gas generated from the battery pack 1 to close the atmospheric port 123, the first magnetic resistor 151 is attached to the second magnetic resistor 152 by magnetic force, as shown in FIG. 9.

In this manner, when the first magnetic resistor 151 and the second magnetic resistor 152 are attached to each other and are in contact with each other, the first magnetic resistor 151 and the second magnetic resistor 152 increase a resistance value on a current flow path. As such, a value (i.e., the current intensity) of the current flowing through the wire 153 is changed.

In other words, when the first magnetic resistor 151 and the second magnetic resistor 152 are separated from each other and current flows through only a path of the wire 153 and a path of the first magnetic resistor 151, a current value (reference current value) A1 becomes relatively high. On the other hand, when the first magnetic resistor 151 and the second magnetic resistor 152 are in contact with each other, the total resistance value increases. As such, a current value (the actual current value) A2 flowing through the wire 153, the first magnetic resistor 151, and the second magnetic resistor 152 becomes lower than the current value A1 when the two magnetic resistors are separated from each other.

Accordingly, the controller 160 reads the value of the current flowing through the wire 153 (the signal value of the auxiliary fire detector). When the read current value is equal to or less than a set value, the controller 160 determines that a fire occurs. When the current value detected by the controller 160 falls below the set value, the controller 160 may determine that a fire occurs.

Alternatively, the controller 160 may be configured to determine that a fire occurs when the amount of change in the current value is equal or greater than a set amount. In this manner, the controller 160 reads the value of the current flowing through the wire 153 of the auxiliary fire detector 150, thereby primarily determining whether a fire occurs in the battery pack 1 from the amount of change in the current value.

Although only one battery pack 1 is shown in FIG. 3, a fire-extinguishing device may be provided in each of a plurality of battery packs mounted in a vehicle. In other words, the pressure-balancing element 110, the ventilation valve 120, and the entry-and-exit path part 128 may be installed in each of the plurality of battery packs 1.

In this case, after the gas path parts are connected to the connection ports 124 of respective ventilation valves 120, the gas path parts are combined into one gas path part 130. The one combined gas path part 130 is connected to an inlet part of the catalytic converter 154. The one gas path part 130, which is connected to the inlet part of the catalytic converter 154, becomes a first path part 131 to be described below. In addition, the first gas detector 140 is installed in the one combined gas path part 130.

Further, a fire-extinguishing agent supply path part 171 connects the fire-extinguishing agent tank 170 to a nozzle 172 that is installed in each battery pack 1. A second valve 182 to be described below is installed in the fire-extinguishing agent supply path part 171, connecting the fire-extinguishing agent tank 170 to the nozzle 172 that is installed in each battery pack 1.

In the fire-extinguishing device formed in a plurality of battery packs 1, in addition to the pressure-balancing element 110 and the ventilation valve 120, the auxiliary fire detector 150 that is installed in the ventilation valve 120 is also installed individually in each battery pack 1.

As a result, the controller 160 may determine the battery pack in which a fire occurs based on the signal from the auxiliary fire detector 150 installed in each battery pack 1. In other words, in one of the battery packs 1, when the current value, which is the value of the signal from the auxiliary fire detector 150, is equal to or less than the set value, or the amount of change in the current value is equal to or greater than the set amount, it may be determined that the corresponding battery pack is a battery pack in which a fire occurs.

The first gas detector 140 is installed in the first path part 131 of the gas path part 130. The first gas detector 140 may be a sensor configured to detect gas generated from the battery cell 3 when a fire occurs, or may be, for example, a carbon monoxide measurement sensor configured to detect the concentration of carbon monoxide (CO).

The first gas detector 140 is connected to the controller 160, thereby inputting a signal according to fire detection to the controller 160. Accordingly, the controller 160 may recognize that a fire occurs inside the battery pack 1 from the signal input from the first gas detector 140.

For example, when the concentration Z1 of carbon monoxide in the gas detected by the first gas detector 140 is equal to or greater than a first set concentration, the controller 160 may determine that a fire occurs inside the battery pack 1.

Accordingly, as described herein, the controller 160 may identify, based on the signal from the auxiliary fire detector 150, what battery pack is actually on fire among all the battery packs 1 mounted in the vehicle. The controller 160 may finally determine that a fire occurs inside the battery pack 1 mounted in the vehicle based on the signal from the first gas detector 140.

The gas path part 130 is connected to the ventilation valve 120. The gas path part 130 includes the first path part 131, connecting the connection port 124 of the ventilation valve 120 to the inlet part of the catalytic converter 154. The gas path part 130 also includes a second path part 132, connecting the outlet part of the catalytic converter 154 to the fire-extinguishing agent tank 170.

In other words, the gas path part 130 is connected to the fire-extinguishing agent tank 170. Accordingly, carbon dioxide converted by the catalytic converter 154 may be supplied to the inside of the fire-extinguishing agent tank 170, in which the fire-extinguishing agent is stored in the liquid state, through the gas path part 130.

In addition, the first gas detector 140 is installed in the first path part 131, and the second gas detector 141 is installed in the second path part 132. A first valve 181, configured to control the opening and closing operations thereof according to the control signal from the controller 160, is installed at the rear end side (the downstream side) of the second gas detector 141 in the second path part 132. A check valve 184, configured to prevent the reverse flow of gas from the catalytic converter 154 to the fire-extinguishing agent tank 170, is installed at the rear end side (the downstream side) of the first valve 181.

The second gas detector 141 may also be a sensor configured to detect gas generated in the battery cell 3 when a fire occurs, or may be a carbon monoxide measurement sensor configured to detect the concentration of carbon monoxide (CO), as in the case of the first gas detector 140. In addition, the second gas detector 141 is also connected to the controller 160, thereby inputting a signal indicating the detection of a fire to the controller 160.

According to the configuration as described herein, in the event of a fire, after the high-temperature flammable gas discharged from the battery pack 1 passes through the pressure-balancing element 110 and the ventilation valve 120, the high-temperature flammable gas passes through the first gas detector 140 while flowing through the first path part 131.

Next, after passing through the first gas detector 140, the high-temperature flammable gas passes through the catalytic converter 154. Next, the high-temperature gas passing through the catalytic converter 154 sequentially passes through the second gas detector 141, the first valve 181, and the check valve 184 while flowing through the second path part 132. The gas passing through the second gas detector 141, the first valve 181, and the check valve 184 along the second path part 132 is introduced into the fire-extinguishing agent tank 170.

The high-temperature gas passing through the second gas detector 141 is a gas containing high-temperature carbon dioxide. The high-temperature carbon dioxide is obtained through the conversion of carbon monoxide while passing through the catalytic converter 154 after being generated and discharged from the battery pack 1 when a fire occurs.

Normally, carbon dioxide, which is the fire-extinguishing agent, is stored in the liquid state in the fire-extinguishing agent tank 170. The fire-extinguishing agent supply path part 171 is connected to the outlet part of the fire-extinguishing agent tank 170.

In addition, the fire-extinguishing agent supply path part 171 is connected to the nozzle 172 installed in the battery pack 1, and the nozzle 172 is installed to spray the fire-extinguishing agent into the battery case 2. The second valve 182, the opening and closing operations of which are controlled by the controller 160, is installed in the fire-extinguishing agent supply path part 171.

As a result, when the high-temperature gas passing through the catalytic converter 154 flows into the fire-extinguishing agent tank 170, the internal temperature of the fire-extinguishing agent tank 170 rises. Thus, the internal pressure of the fire-extinguishing agent tank 170 also increases.

For example, when the second valve 182 is opened, the high-pressure carbon dioxide in the fire-extinguishing agent tank 170 may be discharged to the fire-extinguishing agent supply path part 171 by high-pressure steam without a separate pressurizing source such as a pump or a compressor. The high-pressure carbon dioxide may be sprayed into the battery pack 1 through the nozzle 172.

The carbon dioxide supplied to the nozzle 172 includes the carbon dioxide converted while passing through the catalytic converter 154 and the carbon dioxide stored in the liquid state in the fire-extinguishing agent tank 170. The carbon dioxide supplied thereto is supplied to the battery pack 1, in which a fire occurs, and is used as a fire-extinguishing agent to extinguish the fire.

A third path part 133 branches from the position between the catalytic converter 154 and the first valve 181 in the second path part 132. The third path part 133, branching therefrom, is connected to the inlet part of a buffer tank 155. The third path part 133 has a third valve 183 installed therein, configured to control the opening and closing operations thereof in response to the control signal output from the controller 160.

In addition, one end of a fourth path part 134 is connected to the outlet part of the buffer tank 155, and the other end of the fourth path part 134 is connected to the gas path part 130 between the ventilation valve 120 and the catalytic converter 154, i.e., to the first path part 131.

Referring to FIG. 4, the first gas detector 140, the second gas detector 141, and the auxiliary fire detector 150 are shown as sensing elements. The first valve 181, the second valve 182, and the third valve 183 are shown as operating elements. The controller 160, configured to control the opening and closing operations of each of the valves 181, 182, and 183, is shown as a control element.

The valves 181, 182, and 183 are electronic valves configured to be individually opened and closed in response to the control signal output from the controller 160, and each of the valves 181, 182, and 183 is installed to open and close the flow path of the corresponding path part. A solenoid valve may be used as an example of such a valve.

Upon determining that a fire occurs in the battery pack 1 by the auxiliary fire detector 150 and the first gas detector 140, the controller 160 controls the opening and closing operations of the valves so that gas generated in the battery pack 1 is introduced into the fire-extinguishing agent tank 170 while passing through the catalytic converter 154. The fire-extinguishing agent in the fire-extinguishing agent tank 170 is supplied to the battery pack 1 in which the fire occurs.

The fire-extinguishing device, according to an embodiment of the present disclosure, may further include a warning device configured to provide a warning about the occurrence of a fire. The warning is in response to the control signal output from the controller 160 when the controller 160 determines that a fire occurs in the battery pack 1 based on the signals from the auxiliary fire detector 150 and the first gas detector 140.

For example, the warning device may be a sound output device configured to output a warning sound providing notification of the occurrence of a fire in the vehicle, or a vehicle display device configured to pop up and display a warning message providing notification of the occurrence of a fire therein. The sound output device may include a speaker mounted in the vehicle, and the display device may be a display device (e.g., a graphical user interface) of a cluster.

The configuration of the fire-extinguishing device, according to an embodiment of the present disclosure, has been described in detail herein. As described herein, the present disclosure uses the catalytic converter 154, configured to convert carbon monoxide contained in high-temperature flammable gas, which is generated and discharged when a fire occurs in the battery pack, into carbon dioxide.

In the fire-extinguishing device, according to an embodiment of the present disclosure, the catalytic converter 154 is connected to the first path part 131 of the gas path part 130. Accordingly, at the initial stage of a fire in a battery, the high-temperature flammable gas, generated in the battery cell 3 of the battery pack 1 and passing through the pressure-balancing element 110 and the ventilation valve 120, flows to the catalytic converter 154 through the first path part 131 without being discharged to the outside of the vehicle. As a result, carbon monoxide in the flammable gas is converted into carbon dioxide while the high-temperature flammable gas passes through the catalytic converter 154.

The catalytic converter 154 may be embodied as a case in which a carrier containing a noble metal oxidation catalyst such as platinum, rhodium, and palladium is accommodated. The catalytic converter 154 may also be embodied as a catalytic converter used in a vehicle exhaust gas purification device of the related art or another catalytic converter having a configuration similar thereto.

Gas generated in the event of a fire in a lithium-ion battery contains a large amount of carbon monoxide (CO), a small amount of hydrogen fluoride (HF), a small amount of sulfur dioxide (SO₂), and a trace amount of hydrocarbons (HCl). The main component of the flammable gas is carbon monoxide, which is a flammable gas, and sulfur dioxide, which, as well as carbon monoxide, is also a flammable gas.

According to the catalytic converter, using the oxidation catalyst as described herein, all of the flammable gases may be converted into non-flammable gases. For example, carbon monoxide may be converted into carbon dioxide, which is a non-flammable gas, through the following oxidation reaction.

$$2 \text{CO} \text{+} {\text{Ο}}_{2} \to 2 {\text{CO}}_{2}$$

$${\text{2SO}}_{2} \text{+} {\text{Ο}}_{2} \to 2 {\text{SO}}_{3}$$

FIG. 10 is a view showing the configuration of the catalytic converter usable in the fire-extinguishing device according to an embodiment of the present disclosure. As shown in the drawing, the catalytic converter 154 has a configuration in which a carrier 154b containing a noble metal oxidation catalyst is accommodated in a case 154a.

The case 154a of the catalytic converter 154 is formed of a main body 154c, having a cylindrical shape having a predetermined diameter. The case 154a of the catalytic converter 154 is also formed of an inlet part 154d and an outlet part 154e having a conical shape. The inlet part 154d and the outlet part 154e are integrally coupled to opposite ends of the main body 154c. The first path part 131 is connected to the inlet part 154d, and the second path part 132 is connected to the outlet part 154e, respectively.

When a fire occurs and the gas is discharged from the battery pack 1 too quickly, catalytic oxidation reactivity in the catalytic converter 154 may be insufficient. Therefore, it is required to adjust the gas speed in the catalytic converter 154 by appropriately setting the size of a cross-sectional area of each of the main body 154c and the inlet part 154d. An optimal cross-sectional area combination may be found by repeatedly testing the catalyst reactivity depending on the cross-sectional area of the flow path of each of the main body 154c and the inlet part 154d.

In the present disclosure, the fire-extinguishing agent in the fire-extinguishing agent tank 170 may be automatically supplied to the battery pack 1 using the heat of the gas passing through the catalytic converter 154 without a pressurizing source such as a pump or a compressor. To this end, the high-temperature gas passing through the catalytic converter 154 may be introduced into the fire-extinguishing agent tank 170 through the second path part 132.

When the high-temperature gas passing through the catalytic converter 154 is introduced into the fire-extinguishing agent tank 170 as described herein, high pressure is formed inside the fire-extinguishing agent tank 170 while the heat of the high-temperature gas is supplied.

Accordingly, carbon dioxide, which is a fire-extinguishing agent, may be automatically discharged from the fire-extinguishing agent tank 170 to the outside by the high pressure formed in the fire-extinguishing agent tank 170 without a pump or a compressor. Further, the fire-extinguishing agent discharged from the fire-extinguishing agent tank 170 may be supplied to the nozzle 172 of the battery pack 1, in which a fire occurs, through the fire-extinguishing agent supply path part 171.

Carbon dioxide is gaseous at room temperature. However, carbon dioxide is liquefied when pressure is applied thereto, thereby being liquified and stored in the fire-extinguishing agent tank 170, which is a high-pressure gas container. In addition, when the second valve 182 is opened, carbon dioxide may flow in a liquid (or gaseous) state in the pipe of the fire-extinguishing agent supply path part 171 and may be vaporized in the nozzle 172 and sprayed therethrough when discharged.

Carbon dioxide has great merit in that there is no pollution after use. Further, since liquid carbon dioxide has a very high self-stream pressure, the same may be sprayed with its own intrinsic pressure, without a pressurization source.

In the present disclosure, while a large amount of flammable gas is generated from the battery pack 1 at the initial stage of a battery fire, the gas passing through the catalytic converter 154 is recirculated from the second path part 132 to the first path part 131.

In other words, even though the concentration Z1 of carbon monoxide in the gas, detected by the first gas detector 140, is equal to or greater than the first set concentration, and only when the concentration Z2 of carbon monoxide in the gas detected by the second gas detector 141 is less than a predetermined second set concentration, the first valve 181 is opened when the third valve 183 is closed so that the gas passing through the catalytic converter 154 is supplied to the fire-extinguishing agent tank 170 through the second path part 132.

On the other hand, when the concentration Z2 of carbon monoxide in the gas detected by the second gas detector 141 is equal to or greater than the second set concentration, the third valve 183 is opened when the first valve 181 is closed. As such, the gas passing through the catalytic converter 154 is recirculated to the first path part 131 while sequentially passing through the third path part 133 and the fourth path part 134.

Since gas may flow back into the battery pack 1 due to a sudden pressure change in the gas recirculation process, extra storage space is required to prevent the sudden pressure change.

Accordingly, in the present disclosure, the buffer tank 155 is provided and used as the extra storage space described herein. In other words, some of the recirculated gas is stored in the buffer tank 155, and the rest of the recirculated gas flows to the first path part 131 through the fourth path part 134. Further, among the gases detected by the second gas detector 141, the gas passing through the catalytic converter 154, when the concentration Z2 of carbon monoxide therein falls below the second set concentration, is introduced into and stored in the buffer tank 155 instead of the fire-extinguishing agent tank 170.

Hereinafter, the overall operation of the fire-extinguishing device is described.

In FIG. 3, arrows indicate an air movement path for pressure balancing in the battery pack 1. At normal times when no fire occurs, the pressure-balancing element 110 and the ventilation valve 120 of the fire-extinguishing device are used to allow gas to move between the inside of the battery pack 1 and the outside thereof, and to perform pressure balancing. Normally, the first valve 181 and the second valve 182 are controlled to be in the closed state, and the third valve 183 is controlled to be in the open state.

In addition, gas moves between the inside of the battery pack 1 and the outside thereof through the pressure-balancing element 110 and the ventilation valve 120 when both the atmospheric port 123 and the connection port 124 of the ventilation valve 120 are open. As the gas moves in the direction of the arrow, pressure balancing is performed between the inside of the battery pack 1 and the outside thereof.

Since the connection port 124 is a port that is always open, gas (air) may flow through the connection port 124 and the gas path part 130 connected thereto. In this case, oxygen may be continuously supplied to the catalytic converter 154 through the first path part 131 of the gas path part 130. Accordingly, oxygen to be used for an oxidation reaction may be stored in the oxidation catalyst of the catalytic converter 154.

In addition, when the first valve 181, which is installed in the second path part 132, is closed, the third valve 183, which is installed in the third path part 133, is in the open state. As such, air passing through the catalytic converter 154 may circulate while sequentially passing through the second path part 132, the third path part 133, the buffer tank 155, and the fourth path part 134. In this manner, air does not approach the fire-extinguishing agent tank 170 at normal times and continuously circulates while passing through the catalytic converter 154.

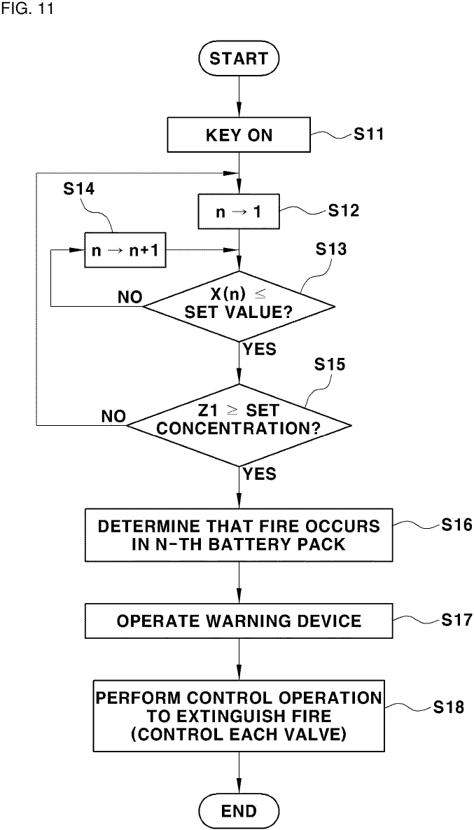

FIG. 11 is a flowchart showing an overall operation process of a battery fire-extinguishing device according to an embodiment of the present disclosure. An example in which a plurality of (n) battery packs are mounted in the vehicle is described below.

In the key-on state of the vehicle in step S11, the controller 160 performs monitoring in real-time whether or not a fire occurs in the battery pack 1 based on the signals from the auxiliary fire detector 150 and the first gas detector 140 in steps S12 to S15. When a fire occurs in the battery pack 1, gas is discharged from the battery pack 1 in which the fire occurs. The gas discharged from the battery pack 1 sequentially passes through the pressure-balancing element 110 and the ventilation valve 120 and then flows through the gas path part 130.

In this case, the controller 160 may determine whether or not a fire occurs in the battery pack 1 based on the signal from the first gas detector 140. The controller 160 may identify the battery pack 1 in which the fire actually occurs among all of the battery packs 1 based on the signal from the auxiliary fire detector 150.

The process of identifying the battery pack in which a fire occurs is described below. The controller 160 performs monitoring in real-time while reading the signal value of the auxiliary fire detector 150 installed in each battery pack 1, i.e., the value of current flowing through the wire 153 of each auxiliary fire detector 150. The controller 160 then checks whether a current value X(n) of each wire 153 is equal to or less than a set value in steps S12 to S14.

Gas, discharged from the battery pack 1 in which the fire occurs and passing through the pressure-balancing element 110, flows into the ventilation valve 120. The gas introduced into the ventilation valve 120 in this manner pushes the valve body 125 and moves the same. The valve body 125 overcomes the force of the spring 126 and is moved to the position at which the valve body 125 closes the atmospheric port 123 so that the gas is not discharged into the atmosphere through the atmospheric port 123 (Refer to FIG. 7).

After the valve body 125 is moved to the position at which the atmospheric port 123 is closed by the same, the first magnetic resistor 151 of the auxiliary fire detector 150 and the second magnetic resistor 152 thereof are attached to each other and are in contact with each other (refer to FIG. 7). For example, the controller 160 may read the value of current flowing through the wire 153.

The controller 160 determines that a fire occurs in the corresponding battery pack 1 when the value of the current flowing through the wire 153 is equal to or less than the set value (or the amount of change in the current value is equal to or greater than the set value). As a result, the controller 160 may identify the battery pack 1 in which a fire occurs among all of the battery packs 1.

In addition, the gas, sequentially passing through the pressure-balancing element 110 and the ventilation valve 120 after being discharged from the battery pack 1, flows into the first path part 131 of the gas path part 130, and then passes through the first gas detector 140 installed in the first path part 131.

In the first gas detector 140, the concentration Z1 of a specific component in the gas passing through the first path part 131, such as carbon monoxide (CO), may be detected, and a signal according to the concentration of the specific component in the gas is output to the controller 160.

Accordingly, the controller 160 checks whether the concentration Z1 of the specific component in the gas is equal to or greater than the first set concentration (e.g., 20 ppm) based on the signal from the first gas detector 140 in step S15. When the concentration Z1 is equal to or greater than the first set concentration (“Z1 ≥ first set temperature”), the controller 160 finally determines that a fire occurs in the battery pack 1 (the “n-th battery pack” in FIG. 10) in which the fire is detected by the auxiliary fire detector 150 in step S16.

In this manner, even though the current value, which is the signal value of the auxiliary fire detector 150, is equal to or less than the set value in step S13, the controller 160 finally determines that a fire occurs in the battery pack 1 only when the concentration Z1 of carbon monoxide (CO) in the gas detected by the first gas detector 140 in step S15 is equal to or greater than the first set concentration, thereby reducing the risk of malfunction.

Next, when finally determining that a fire occurs in the battery pack 1, the controller 160 operates the warning device to warn a driver and passengers of the fire in step S17 and performs a control operation to extinguish the fire in step S18.

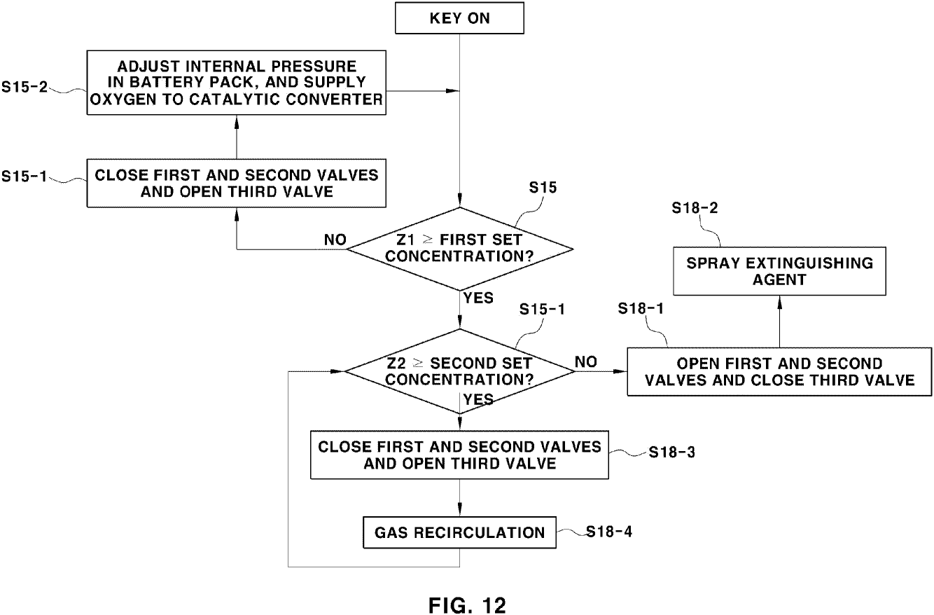

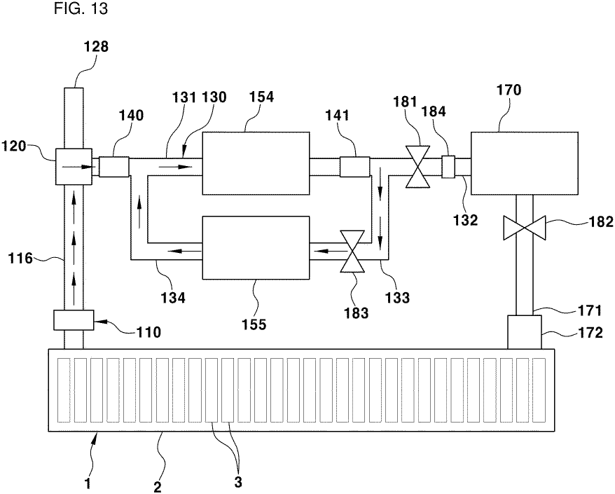

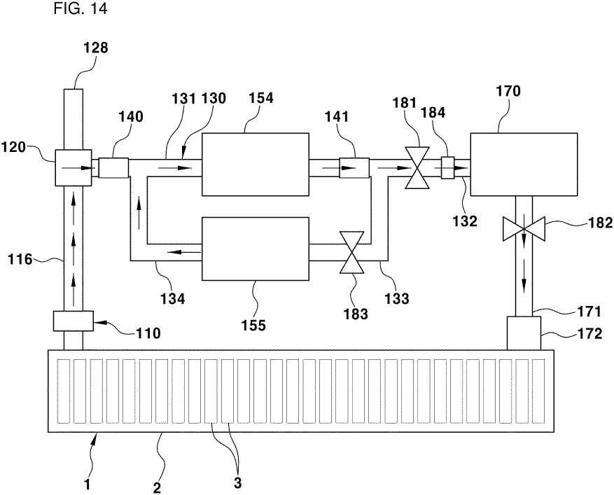

FIG. 12 is a flowchart showing an operation process of the battery fire-extinguishing device, according to an embodiment of the present disclosure, when a battery fire occurs. FIGS. 13 and 14 are views showing a gas flow path in the battery fire-extinguishing device, according to an embodiment of the present disclosure, when the battery fire occurs. Step S15 in FIG. 12 is the same as step S15 in FIG. 11, and some steps shown in FIG. 11 are omitted in FIG. 12.

When a fire is not detected in the battery pack in step S15 (“Z1 < first set concentration”), each valve is controlled to be in the control state at normal times by the controller 16. In detail, the first valve 181 and the second valve 182 are controlled to be in the closed state, and the third valve 183 is controlled to be in the open state by the controller 16 in step S15-1. In this state, the internal pressure of the battery pack 1 may be adjusted, and oxygen may be supplied to the catalytic converter 154 in step S15-2.

On the other hand, when determining that a fire occurs in the battery pack 1 in step S15 (“Z1 ≥ first set concentration”), the controller 160 compares the concentration Z2 of carbon monoxide (CO) detected by the second gas detector 141 with the second set concentration (e.g., 3 ppm) in step S15-1.

The second gas detector 141 detects the concentration Z2 of carbon monoxide (CO) in the gas passing through the catalytic converter 154. When the concentration Z2 detected by the second gas detector 141 is equal to or greater than the second set concentration, the controller 160 determines that a large amount of flammable gas is discharged from the battery pack 1 in which the fire occurs.

During mass discharge of this flammable gas, the third valve 183 is opened when the first valve 181 and the second valve 182 are closed in step S18-3, and the gas passing through the catalytic converter 154 is recirculated to the first path part 131 while sequentially passing through the third path part 133 and the fourth path part 134. Thereafter, the gas recirculated to the first path part 131 may pass through the catalytic converter 154 again. In addition, some of the recirculated gas is stored in the buffer tank 155 in step S18-4.

On the other hand, when the concentration Z2 of carbon monoxide (CO), detected by the second gas detector 141, is less than the second set concentration (“Z2 < second set concentration”) after the time period of the mass discharge of flammable gas has elapsed, the controller 160 opens the first valve 181, opens the second valve 182, and closes the third valve 183 in step S18-1.

Accordingly, the high-temperature gas passing through the catalytic converter 154 is introduced into the fire-extinguishing agent tank 170 through the second path part 132, and the internal pressure of the fire-extinguishing agent tank 170 becomes high. As a result, carbon dioxide introduced into the fire-extinguishing agent tank 170 and the fire-extinguishing agent (carbon dioxide) stored in the liquid state inside the fire-extinguishing agent tank 170 are discharged to the outside by high-pressure steam in the mixed state thereof.

Carbon dioxide discharged to the outside, as described herein, is supplied to the nozzle 172 of the battery pack 1 in which the fire occurs through the fire-extinguishing agent supply path part 171. The carbon dioxide, which is a fire-extinguishing agent, is finally sprayed into the battery pack 1 through the nozzle 172, thereby extinguishing the fire in the battery pack 1 in step S18-2.

In this manner, the battery fire-extinguishing device, according to the present disclosure and the control process thereof, has been described in detail. According to the present disclosure described herein, it is possible to quickly and accurately detect a fire occurring in a vehicle battery, and to effectively extinguish the fire immediately upon detection.

Particularly, in the present disclosure, carbon monoxide in the high-temperature flammable gas discharged from a battery pack in the event of a fire is converted into carbon dioxide using a catalytic converter. Thereafter, the converted carbon dioxide and a fire-extinguishing agent stored in a fire-extinguishing agent tank may be supplied to the battery pack to extinguish the fire.

In addition, the high-temperature carbon dioxide obtained through the conversion of the flammable gas is supplied to the fire-extinguishing agent tank. Accordingly, as the pressure in the fire-extinguishing agent tank increases, the fire-extinguishing agent in the fire-extinguishing agent tank may be supplied to the battery pack without a separate pressurization source, such as a pump or a compressor. Therefore, it is possible to reduce device installation costs and extinguish a fire even in an emergency situation in which no power is supplied to drive the pump or the compressor.

In addition, in the present disclosure, when a simple and inexpensive auxiliary fire detector is installed in each battery pack and a gas detector (gas concentration measurement sensor) configured to measure gas concentration is installed in a common gas path part to which each battery pack is connected, it is possible to detect a battery fire. It is further possible to identify a battery pack in which a fire occurs using only a minimum number of gas detectors with respect to a plurality of battery packs.

Further, a low-cost auxiliary fire detector is used to classify and identify a battery pack in which a fire occurs. A first gas detector and a second gas detector are installed in the common gas path part to finally confirm the occurrence of a battery fire, thereby making it possible to reliably prevent erroneous detection of a fire and to significantly reduce costs compared to the case in which an expensive gas concentration measurement sensor is installed in each battery pack as in the related art.

Additionally, since the fire-extinguishing device of the present disclosure performs a function of a pressure-balancing element of the related art, pressure balancing of the battery pack can be performed without installing a plurality of pressure-balancing elements in the battery pack.

As is apparent from the description herein, the present disclosure provides a fire-extinguishing device for a vehicle battery capable of quickly and accurately detecting a fire occurring in a battery pack, and effectively extinguishing the fire immediately upon detection.

Particularly, the present disclosure provides a catalytic converter configured to convert carbon monoxide in the high-temperature flammable gas discharged from the battery pack in the event of a fire into carbon dioxide. After that, the converted carbon dioxide and a fire-extinguishing agent stored in a fire-extinguishing agent tank may be supplied to the battery pack, thereby making it possible to extinguish the fire.

In addition, the high-temperature carbon dioxide obtained through the conversion of the flammable gas is supplied to the fire-extinguishing agent tank. Accordingly, as the pressure in the fire-extinguishing agent tank is increased, the fire-extinguishing agent stored in the fire-extinguishing agent tank may be supplied to the battery pack without a separate pressurization source, such as a pump or a compressor. Therefore, device installation costs may be reduced, and a fire may be extinguished even in an emergency situation in which no power is supplied to drive the pump or the compressor.

In addition, in the present disclosure, a simple and inexpensive auxiliary fire detector is installed in each battery pack, and a gas detector (gas concentration measurement sensor) configured to measure gas concentration is installed in a common gas path part to which each battery pack is connected. Thus, it is possible to detect a battery fire and to identify a battery pack in which a fire occurs using only a minimum number of gas detectors for a plurality of battery packs.

Further, it is possible to reliably prevent false detection of a fire and to significantly reduce costs by using a low-cost auxiliary fire detector configured to classify and identify a battery pack in which a fire occurs. Furthermore, it is possible to reliably prevent false detection of a fire and significantly reduce costs by also using first and second gas detectors installed in the common gas path part and configured to finally confirm the occurrence of a battery fire. This is compared to the related art, in which an expensive gas concentration measurement sensor is installed in each battery pack.

Additionally, according to the present disclosure, since the fire-extinguishing device performs a function of a pressure-balancing element of the related art, pressure balancing of the battery pack may be performed without installing a plurality of pressure-balancing elements in the battery pack.

The disclosure has been described in detail with reference to embodiments thereof. However, it should be appreciated by those having ordinary skill in the art that changes may be made in these embodiments without departing from the principles and spirit of the inventive concept, the scope of which is defined in the appended claims and equivalents thereto.

What is claimed is:

1. A fire-extinguishing device for a vehicle battery, comprising:
a gas discharge part installed in a battery pack and configured to discharge gas inside the battery pack;
a gas path part configured to permit flow of gas generated in the battery pack and discharged through the gas discharge part in an event of a fire;
a catalytic converter installed in the gas path part and configured to convert carbon monoxide in gas flowing through the gas path part into carbon dioxide;
a fire-extinguishing agent tank configured to store a fire-extinguishing agent and to be connected to the gas path part, the fire-extinguishing agent tank allowing the carbon dioxide converted by the catalytic converter to flow thereinto; and
a fire-extinguishing agent supply path part connecting the fire-extinguishing agent tank to the battery pack,
wherein gas flowing into the fire-extinguishing agent tank and the fire-extinguishing agent stored therein are supplied from the fire-extinguishing agent tank to the battery pack through the fire-extinguishing agent supply path part by pressure in the fire-extinguishing agent tank to extinguish the fire, and
wherein the pressure in the fire-extinguishing agent tank rises while the gas passing through the catalytic converter flows into the fire-extinguishing agent tank.

2. The fire-extinguishing device of claim 1, further comprising:
a first gas detector installed in the gas path part and configured to detect a fire occurring in the battery pack;
a controller configured to output a control signal when the fire is detected in the battery pack by the first gas detector, the control signal being provided to extinguish the detected fire; and
valves installed in the gas path part and the fire-extinguishing agent supply path part, the valves being configured to control opening and closing operations thereof in response to the control signal output from the controller.

3. The fire-extinguishing device of claim 2, further comprising a second gas detector installed in a second path part, which is a gas path part on a side downstream of the catalytic converter, and configured to detect a concentration of carbon monoxide in the gas passing through the catalytic converter,
wherein the first gas detector is installed in a first path part, which is a gas path part on a side upstream of the catalytic converter, and configured to detect a concentration of carbon monoxide in the gas discharged through the gas discharge part.

4. The fire-extinguishing device of claim 3, further comprising:
a third path part, branching from the second path part connecting the catalytic converter to the fire-extinguishing agent tank, wherein the third path part connects the second path part to an inlet part of a buffer tank comprising the gas passing through the catalytic converter collected and stored therein; and
a fourth path part connecting an outlet part of the buffer tank to the first path part.

5. The fire-extinguishing device of claim 4, wherein the valves configured to control the opening and closing operations thereof in response to the control signal output from the controller comprise:
a first valve installed at a position between a branch point having the third path part branching from the second path part and the fire-extinguishing agent tank; and
a second valve installed in the third path part.

6. The fire-extinguishing device of claim 5, wherein the first valve is maintained in a closed state and a third valve is maintained in an open state at normal times when no fire occurs.

7. The fire-extinguishing device of claim 5, wherein the controller maintains the first valve in a closed state and maintains a third valve in an open state when the concentration of carbon monoxide detected by the first gas detector is equal to or greater than a first set concentration, and the concentration of carbon monoxide detected by the second gas detector is equal to or greater than a second set concentration.

8. The fire-extinguishing device of claim 5, wherein the controller performs a control operation to open the first valve and performs a control operation to close a third valve so that the gas passing through the catalytic converter is supplied to the fire-extinguishing agent tank through the second path part when the concentration of carbon monoxide detected by the first gas detector is equal to or greater than a first set concentration, and the concentration of carbon monoxide detected by the second gas detector is less than a second set concentration.

9. The fire-extinguishing device of claim 2, wherein:
the valves configured to control the opening and closing operations thereof in response to the control signal comprise a second valve installed in the fire-extinguishing agent supply path part, and
the controller is configured to output the control signal to open the second valve when the first gas detector detects the fire in the battery pack.

10. The fire-extinguishing device of claim 4, wherein a check valve, configured to prevent backflow of gas flowing into the fire-extinguishing agent tank after passing through the catalytic converter, is installed at a position between a branch point having the third path part branching from the second path part and the fire-extinguishing agent tank.

11. The fire-extinguishing device of claim 1, further comprising a ventilation valve connected to the gas discharge part, the ventilation valve comprising a connection port configured to be opened by the gas discharged through the gas discharge part in the event of the fire,
wherein the gas path part is connected to the connection port of the ventilation valve so that the gas discharged through the gas discharge part in the event of the fire flows to the gas path part through the opened connection port.

12. The fire-extinguishing device of claim 11, wherein:
the gas discharge part is a pressure-balancing element comprising a path configured to allow gas to move in both directions therethrough between an inside of a battery case of the battery pack and an outside thereof, and
the pressure-balancing element comprises:
a vent part provided in a shape protruding from the battery case, the vent part comprising a vent hole configured to allow the gas to enter and exit therethrough,
a connector coupled to the vent part, the connector having an internal space communicating with an internal space in the vent part and an internal space in the battery case through the vent hole, and
a venting path part coupled to the connector so that an internal path thereof communicates with the internal space in the connector, the venting path part being connected to the ventilation valve.

13. The fire-extinguishing device of claim 12, wherein the vent part comprises a ventilation waterproof membrane member configured to permit flow of gas and to prevent moisture from flowing into the battery case, and
wherein the ventilation waterproof membrane member is installed in the vent hole in the vent part.

14. The fire-extinguishing device of claim 11, wherein:
the ventilation valve comprises a ventilation port connected to the gas discharge part, an atmospheric port opened to atmosphere and configured to allow gas to move between the atmospheric port and the atmosphere, and a connection port having the gas path part connected thereto, and
the atmospheric port is closed by gas generated inside a battery case and introduced through the gas discharge part in the event of the fire in the battery pack.

15. The fire-extinguishing device of claim 14, wherein:
the ventilation valve comprises:
a valve housing comprising the ventilation port, the atmospheric port, and the connection port;
a valve body installed in an internal space in the valve housing and configured to be moved to close the atmospheric port by the gas introduced through the gas discharge part; and
a spring installed to support the valve body in the internal space in the valve housing;
wherein the connection port in the valve housing is provided as an open port at all times regardless of a position of the valve body.

16. The fire-extinguishing device of claim 15, further comprising an auxiliary fire detector installed in the ventilation valve to detect fire occurrence in the battery pack,
wherein a controller is configured to determine whether or not a fire occurs in the battery pack and to determine the battery pack in which the fire occurs based on signals from a first gas detector and the auxiliary fire detector.

17. The fire-extinguishing device of claim 16, wherein the auxiliary fire detector comprises:
a first magnetic resistor installed in the valve body;
a second magnetic resistor fixedly installed in the valve housing so that the first magnetic resistor is attached thereto when the valve body is moved to a position at which the atmospheric port is closed; and
a wire configured to connect the second magnetic resistor and the controller to allow current to flow therebetween.

18. The fire-extinguishing device of claim 17, wherein:
the controller is provided to apply current to the wire and to detect the current flowing through the wire; and
the controller is configured to determine that a fire occurs in the battery pack when a detected current value is equal to or less than a set value or when an amount of change in the detected current value is equal to or greater than a set amount.
